(19) United States
(12) Patent Application Publication
(10) Pub. No.: US 2020/0365404 A1
(43) Pub. Date: Nov. 19, 2020

(54) BEVEL PEELING AND DEFECTIVITY SOLUTION FOR SUBSTRATE PROCESSING

(71) Applicant: Applied Materials, Inc., Santa Clara, CA (US)

(72) Inventor: Abdul Aziz KHAJA, San Jose, CA (US)

(21) Appl. No.: 16/856,202

(22) Filed: Apr. 23, 2020

Related U.S. Application Data
(60) Provisional application No. 62/848,436, filed on May 15, 2019.

(51) Int. Cl. H01L 21/02; H01J 37/32; C23C 16/04

(52) U.S. Cl. CPC H01L 21/02658; H01J 37/32174; C23C 16/042; H01J 2237/3328; H01J 37/32642; H01J 2237/3321; H01L 21/0262

(57) ABSTRACT

A method and apparatus for reducing bevel peeling during and after plasma enhanced chemical vapor deposition (PECVD) of a material layer on a substrate is disclosed. In one embodiment a method of processing a substrate includes positioning a substrate in a processing volume of a processing chamber, plasma treating the surface of the substrate with a treatment plasma formed of a treatment gas, chucking the substrate to the substrate support, and depositing a material layer onto the surface of the substrate by exposing the surface of the substrate to a deposition plasma. Here, the treatment gas is substantially free of carbon, silicon, or metal deposition precursors, and an RF power used to form the treatment plasma is less than about 1.42 Watts per cm² of substrate surface (W/cm²). The deposition plasma is formed from one or a combination of a carbon, silicon, or metal precursors, and an RF power used to ignite and maintain the deposition plasma is more than about 2.12 W/cm².

### CROSS-REFERENCE TO RELATED APPLICATIONS

This application claims priority to U.S. Provisional Patent Application Ser. No. 62/848,436 filed on May 15, 2019, which is herein incorporated by reference in its entirety.

### BACKGROUND

### Field

Embodiments described herein generally relate to the field of semiconductor device fabrication.

### Description of the Related Art

Integrated circuits have evolved into complex devices that can include millions of transistors, capacitors, and resistors on a single chip. The evolution of chip designs continually involve faster circuitry and greater circuit density. The demands for faster circuits with greater circuit densities impose corresponding demands on the materials used to fabricate such integrated circuits. In particular, as the dimensions of integrated circuit components are reduced to the sub-micron scale, low resistivity conductive materials, as well as low dielectric constant insulating materials are used to obtain suitable electrical performance from such components.

The demands for greater integrated circuit densities also impose demands on the process sequences used in the manufacture of integrated circuit components. For example, in process sequences that use conventional photolithographic techniques, a layer of energy sensitive resist is formed over a stack of material layers deposited on a substrate. The energy sensitive resist layer is exposed to an image of a pattern to form a photoresist mask. Thereafter, the mask pattern is transferred to one or more of the material layers of the stack using an etch process. The chemical etchant used in the etch process is selected to have a greater etch selectivity for the material layers of the stack than for the mask of energy sensitive resist. That is, the chemical etchant etches the one or more layers of the material stack at a rate much faster than the energy sensitive resist. The etch selectivity to the one or more material layers of the stack over the resist prevents the energy sensitive resist from being consumed prior to completion of the pattern transfer.

As the pattern dimensions are reduced, the thickness of the energy sensitive resist is correspondingly reduced in order to control pattern resolution. Such thin resist layers can be insufficient to mask underlying material layers during the pattern transfer process due to attack by the chemical etchant. An intermediate layer (e.g., silicon oxynitride, silicon carbine or carbon film), called a hardmask, is often used between the energy sensitive resist layer and the underlying material layers to facilitate pattern transfer because of greater resistance to the chemical etchant.

Often, hardmask materials deposited onto the substrate surface are also undesirably deposited onto the upper and lower surfaces of the circumferential edge of the substrate, e.g., the circumferential bevel edge of the substrate. When the deposited hardmask material is weakly adhered to the underlying substrate material the hardmask material may delaminate from the bevel surfaces and cause undesirable particulate defectivity to transfer to the active surface of the substrate where it can ultimately cause failure of the to-be-formed devices.

Accordingly, there is a need in the art for methods and apparatus to reduce or substantially eliminate material deposition onto, and delamination of material layers from, the beveled surfaces of a substrate.

### SUMMARY

Embodiments of the present disclosure generally relate to the field of semiconductor device manufacturing, and more particularly, to methods and apparatus for reducing or substantially eliminating post deposition material peeling from the bevel surfaces of a substrate and thus reducing and or substantially eliminating particulate defectivity associated therewith.

In one embodiment, a method of processing a substrate includes positioning the substrate on a substrate support assembly disposed in a processing volume of a processing chamber, plasma treating a surface of the substrate with a treatment plasma formed of a treatment gas, chucking the substrate to the substrate support, and depositing an amorphous carbon layer onto the surface of the substrate. Here, the treatment gas is substantially free of carbon, silicon, or metal deposition precursors, and an RF power used to form the treatment plasma is less than about 1.42 Watts per cm² of substrate surface (W/cm²). In some embodiments, plasma treating the surface of the substrate includes exposing a silicon surface proximate to a circumferential edge of the substrate to the treatment plasma.

In another embodiment, a method of processing a substrate includes positioning the substrate on a substrate support assembly disposed in a processing volume of a processing chamber and heating the substrate to a temperature of about 300° C. or more. The method further includes maintaining the substrate at about 300° C. or more at for at least about 60 seconds and depositing an amorphous carbon layer on a surface of the substrate. Depositing the amorphous carbon layer onto the substrate includes flowing one or more deposition material precursors into the processing volume, igniting and maintaining a deposition plasma of the one or more deposition material precursors by applying an RF power to a showerhead disposed in the processing volume, where the RF power is about 2.12 Watts per cm² of substrate surface (W/cm²) or more, and exposing a surface of the substrate to the deposition plasma to deposit an amorphous carbon layer thereon.

In another embodiment, a substrate processing system is provided. The processing system includes a processing chamber having a chamber lid assembly, one or more chamber sidewalls, and a chamber base which collectively define a processing volume, a substrate support assembly disposed in the processing volume, and a computer readable medium having instructions stored thereon for a material deposition method. The substrate support assembly features a substrate supporting portion and an annular portion extending upwardly from the substrate supporting portion. The annular portion is disposed radially outward of the substrate supporting portion and a radially inward facing surface of the annular portion is sized to be spaced apart from a circumferential edge of a to-be-processed substrate by a distance of about 5 mm or less. The material deposition method includes flowing one or more deposition material precursors into the processing volume, igniting and maintaining a deposition plasma of the one or more deposition material precursors by applying an RF power to a showerhead of the chamber lid assembly, and exposing the surface of the substrate to the deposition plasma to deposit an amorphous carbon layer thereon. In some embodiments, the RF power is about 2.12 Watts per cm² of substrate surface (W/cm²) or more.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic cross sectional view of a bevel edge of a substrate, according to one embodiment, which may benefit from the methods set forth herein.

FIG. 1B is a schematic illustration of a contact angle of a water droplet disposed on a surface.

FIG. 2 is a schematic cross sectional view of an exemplary processing chamber which may be used to practice the methods set forth herein, according to one embodiment.

FIGS. 3A-3C are schematic cross sectional views of portions of respective substrate supports and edge rings which may be used in the processing chamber described in FIG. 2, according to one or more embodiments.

FIG. 4 is a flow diagram illustrating a method of processing a substrate, according to one embodiment.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Embodiments herein relate to methods and apparatus for reducing or substantially eliminating post deposition material delamination from the bevel surfaces of a substrate (bevel peeling) thus reducing or substantially eliminating particulate defectivity associated therewith. Generally, the methods include pre-treating the substrate surface and more particularly, a bevel edge of the substrate surface, prior to a material deposition process to improve adhesion between the subsequently deposited material layer and the bevel edge surfaces. In some embodiments, the methods incorporate hardware configurations, e.g., substrate support assemblies, which prevent or substantially reduce undesired material deposition on the circumferential edge of substrate. In some embodiments, the methods and hardware configurations are used, alone or in combination, to reduce and/or substantially eliminate delamination of carbon hard mask material from the bevel edge of a substrate. For example, in some embodiments, the methods are used to pre-treat a substrate surface to improve adhesion between the subsequently deposited carbon hard mask material and the surfaces of the bevel edge. In some embodiments, the methods and hardware configurations are used to prevent and/or substantially reduce deposition of the carbon hard mask material on the bevel edge.

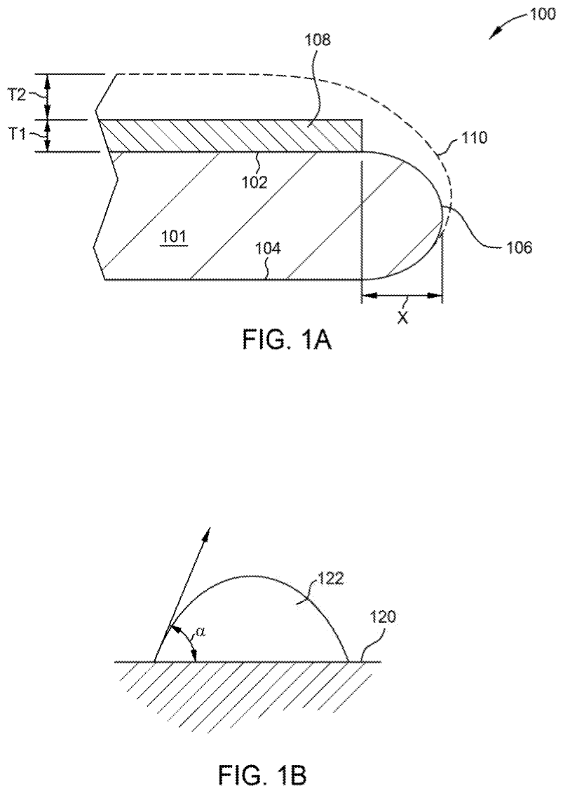

FIG. 1A is a schematic cross sectional view of a portion of substrate 100 which may be processed using the methods set forth herein. The substrate 100 may be formed from any materials and material layers suitable for use in an electronic device manufacturing process, such as silicon, silicon oxide, strained silicon, silicon on insulator (SOI), carbon doped silicon oxides, a-Si, doped silicon, germanium, gallium arsenide, glass, sapphire, metals, metal nitrides, metal alloys, and combinations thereof.

Here, the substrate 100 comprises a monocrystalline silicon wafer 101 having an active surface, here a first surface 102, a second surface 104 opposite the first surface 102, a beveled circumferential edge, here a bevel edge 106 connecting the first and second surfaces 102, 104, and a material layer stack 108 disposed on the first surface 102. In some embodiments, the material layer stack 108 includes a plurality of material layers which may be used to form a 3D vertical NAND structure, e.g., alternating pairs of dielectric material layers used to form discrete charge storage segments. For example, in some embodiments the material layer stack 108 includes alternating pairs of oxide/nitride layers, e.g., silicon oxide/silicon nitride layers. In some embodiments, the material layer stack 108 includes 32 or more layers of alternating pairs of silicon oxide and silicon nitride, e.g., 48 or more, 64 or more, 96 or more, or, for example 128 layers or more. In other embodiments, the material layer stack 108 may include a plurality of alternating oxide and nitride materials, one or more oxide or nitride materials, polysilicon or amorphous silicon materials, oxides alternating with amorphous silicon, oxides alternating with polysilicon, undoped silicon alternating with doped silicon, undoped polysilicon alternating with doped polysilicon, or undoped amorphous silicon alternating with doped amorphous silicon. In some embodiments, the material layer stack 108 has a combined thickness T1 of about 1 μm or more, such as about 1.5 μm or more, about 2 μm or more, about 2.5 μm or more, or about 3.0 μm or more.

In some embodiments, the methods provided herein include depositing an amorphous carbon layer onto a surface of the substrate 100, here onto a surface of the material layer stack 108, to form a carbon hard mask layer 110 (shown in phantom). In some embodiments, the carbon hard mask layer 110 is deposited to a thickness T2 of about 1 kÅ or more, about 500 kÅ or more, about 1000 kÅ or more, or for example within a range from about 1 kÅ to about 40 kA, such as within a range from about 10 kÅ to about 40 kA.

In some embodiments, a portion of the material layer stack 108 and/or one or more material layers disposed therebeneath (not shown) are removed from the beveled edge 106 before the carbon hard mask layer 110 is formed on the substrate 100 using a bevel etch process. The bevel etch process typically removes material from within a distance X from the circumferential edge of the substrate 100, such as about 0.5 mm or more, about 1 mm or more, about 2 mm or more, or between about 0.5 mm and about 2 mm from the circumferential edge of the substrate 100 to expose a surface of the monocrystalline silicon wafer 101 therebeneath. Thus, at least a portion of the carbon hard mask layer 110 may be deposited onto an exposed monocrystalline silicon surface disposed proximate to the circumferential edge of the substrate 100.

Typically, when used, the bevel etch process is one of a wet etch process or a dry etch process. In a wet process the bevel edge 106 may be exposed to an aqueous solution such as a piranha solution (i.e., a solution of H₂SO₄, H₂O, and H₂O₂) or an HF solution. In a dry etch process, the bevel edge 106 may be exposed to plasma formed of a fluorine-containing gas, e.g., SF₆, NF₃, CₓF_{y} (e.g., CF₄, C₂F₄, C₂F₆), or CₓF_{y}H₂ (e.g., C₃HF, CHF₃, CH₂F₂, C₂H₂F₄), an oxygen-containing gas, e.g., O₂; N₂O, CO, COS, CO₂, or a combination thereof.

Depending on the type of bevel etch process used (if any), and/or material layers removed from the surfaces of the bevel edge 106, the resulting surfaces of the bevel edge 106 may be hydrophilic or hydrophobic. For example, a wet etch bevel etch process using a piranha solution where all of the material layers are removed to expose a monocrystalline silicon wafer 101 therebeneath typically results in a bevel edge 106 having a hydrophilic surface. A wet etch process using an HF solution where all of the material layers are removed to expose the monocrystalline silicon wafer 101 therebeneath typically results in a bevel edge 106 having a hydrophobic surface. Herein, a “hydrophilic surface” is one where a contact angle of a water droplet disposed on the surface is less than 90 degrees and a “hydrophobic surface” is one where a contact angle of a water droplet is 90 degrees or more. FIG. 1B schematically illustrates a surface 120 where a contact angle α of a water droplet 122 disposed on the surface 120 is less than 90 degrees, i.e., a hydrophilic surface.

Generally, the roughness and/or the hydrophobicity of the surfaces of the bevel edge 106 impact the adhesion of the subsequently formed carbon hard mask layer 110 thereto. For example, the adhesive strength between the carbon hard mask layer 110 and the beveled edge 106 having a hydrophobic surface is typically lower than the adhesive strength of the carbon hard mask layer 110 to the beveled edge 106 having a hydrophilic surface. Thus, in some embodiments, the methods herein include plasma treating the bevel edges 106 before forming the carbon hard mask layer 110 thereon to desirably reduce the hydrophobicity thereof, and thus increase the adhesive strength between the carbon hard mask layer 110 and the bevel edge 106.

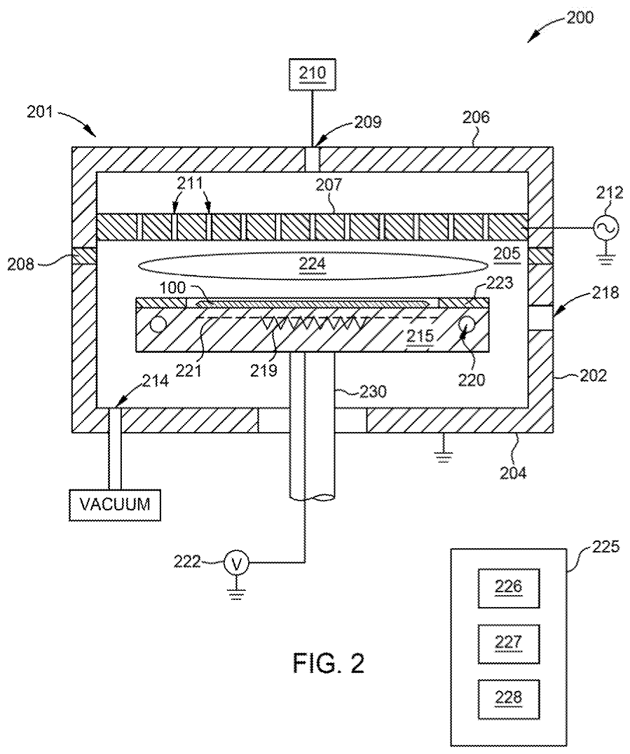

FIG. 2 is a schematic cross sectional view of an exemplary processing chamber, here a plasma enhanced chemical vapor deposition (PECVD) chamber which may be used to practice the methods set forth herein. Other exemplary deposition chambers that may be used to practice the methods described herein include the CENTURA® systems which may use a DXZ® processing chamber, PRECISION 5000® systems, PRODUCER® systems, PRODUCER® GT™ systems, PRODUCER® XP Precision™ systems, and PRODUCER® SE™ systems, all of which are commercially available from Applied Materials, Inc., of Santa Clara, Calif. as well as suitable deposition chambers from other manufacturers.

A processing chamber 200 includes a chamber lid assembly 201, one or more chamber sidewalls 202, and a chamber base 204. The chamber lid assembly 201 includes a chamber lid 206, a showerhead 207 disposed in the chamber lid 206, and an electrically insulating ring 208, disposed between the chamber lid 206 and the one or more sidewalls 202. The showerhead 207, one or more chamber sidewalls 202, and the chamber base 204 together define a processing volume 205. A gas inlet 209, disposed through the chamber lid 206 is fluidly coupled to a gas source 210. The showerhead 207, having a plurality of openings 211 disposed therethrough, is used to uniformly distribute processing gases from the gas source 210 into the processing volume 205. The showerhead 207 is electrically coupled to a first power supply 212, such as an RF power supply, which supplies power to ignite and maintain a plasma 224 of the processing gas through capacitive coupling therewith. Herein, the RF power has a frequency between about 400 kHz and about 40 MHz, for example about 400 kHz or about 13.56 MHz.

The processing volume 205 is fluidly coupled to a vacuum source, such as to one or more dedicated vacuum pumps, through a vacuum outlet 214, which maintains the processing volume 205 at sub-atmospheric conditions and evacuates the processing gas and other gases therefrom. A substrate support 215, disposed in the processing volume 205, is disposed on a movable support shaft 230 sealingly extending through the chamber base 204, such as being surrounded by bellows (not shown) in the region below the chamber base 204. Typically, the processing chamber 200 is configured to facilitate transferring of a substrate 100 to and from the substrate support 215 through an opening 218 in one of the one or more sidewalls 202, which is conventionally sealed with a door or a valve (not shown) during substrate processing.

Here, a substrate 100, disposed on the substrate support 215, is maintained at a desired processing temperature using one or both of a heater, such as a resistive heating element 219, and one or more cooling channels 220 disposed in the substrate support 215. Typically, the one or more cooling channels 220 are fluidly coupled to a coolant source (not shown), such as a modified water source having relatively high electrical resistance or a refrigerant source. The substrate support 215 is formed of a dielectric material, such as metal oxide or metal nitride ceramic material, and includes one or more chucking electrodes 221 embedded therein. The one or more chucking electrodes 221 are used to secure the substrate 100 to the substrate support 215 by providing a potential between the substrate 100 and the one or more chucking electrodes 221. The potential between the substrate 100 and the one or more chucking electrodes 221 results in an electrostatic chucking (ESC) attraction force therebetween. Herein, the one or more chucking electrodes 221 are electrically coupled to a respective chucking power supply 222, such as a DC power supply, which provides a chucking voltage thereto of between about −5000 V and about +5000.

In some embodiments, an annular edge ring 223 is circumferentially disposed on, and proximate to the edge of, the plasma facing surface of the substrate support 215. The edge ring 223 is used to reduce non-uniform substrate-center to substrate-edge material deposition thickness attributable to changes in the properties of the processing plasma above the circumferential edge of the substrate 100. Processing plasma properties typically include the shape of the plasma 224 over the substrate 100 and edge ring 223, the degree of ionization of processing gases forming the plasma 224, and the uniformity of ionization of processing gases across the plasma 224.

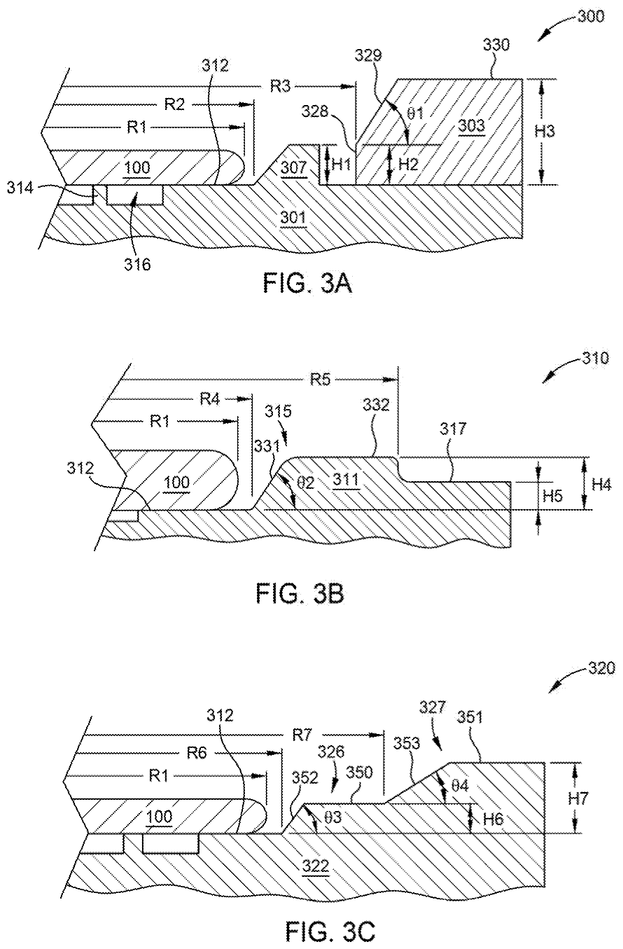

Here, the edge ring 223 has a radially inward facing surface which circumscribes the substrate 100 and is spaced apart therefrom by a gap to provide mechanical clearance for transferring the substrate 100 to and from the surface of the substrate support 215. Too wide a gap and plasma generated species will penetrate into the gap and under a circumferential edge of the substrate 100 to undesirably deposit material thereon. Thus, in some embodiments, the substrate facing surface, e.g., the innermost radially inward facing surface, of the edge ring 223 is spaced apart from the circumferential edge of the substrate 100 by a gap of less than about 5 mm, such as less than about 4 mm, less than about 3 mm, or between about 0.5 mm and about 5 mm, for example between about 1 mm and about 4 mm. Alternative embodiments of substrate supports and/or edge rings which may be used to control plasma properties proximate to the circumferential edge of the substrate and to minimize deposition on the bevel edge thereof are described in FIGS. 3A-3C.

Here, operation of the processing chamber 200 is facilitated by a system controller 225. The system controller 225 includes a programmable central processing unit (CPU 226) which is operable with a memory 227 (e.g., non-volatile memory) and support circuits 228. The support circuits 228 are conventionally coupled to the CPU 226 and comprise cache, clock circuits, input/output subsystems, power supplies, and the like, and combinations thereof coupled to the various components the processing chamber 200, to facilitate control of substrate processing. For example, in some embodiments the CPU 226 is one of any form of general purpose computer processor used in an industrial setting, such as a programmable logic controller (PLC), for controlling various processing chamber components and sub-processors. The memory 227, coupled to the CPU 226, is non-transitory and is typically one or more of readily available memory such as random access memory (RAM), read only memory (ROM), floppy disk drive, hard disk, or any other form of digital storage, local or remote.

Typically, the memory 227 is in the form of a computer-readable storage media containing instructions (e.g., non-volatile memory), that when executed by the CPU 226, facilitates the operation of the processing chamber. The instructions in the memory 227 are in the form of a program product such as a program that implements the methods of the present disclosure (e.g., middleware application, equipment software application etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying out computer-readable instructions that direct the functions of the methods described herein, are embodiments of the present disclosure.

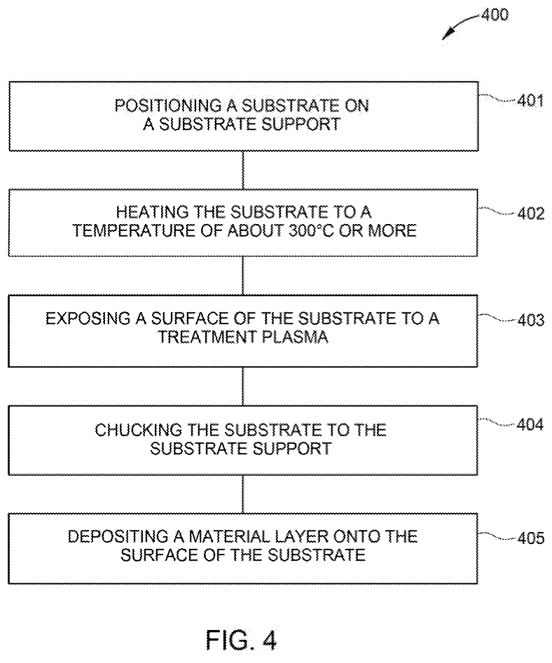

FIGS. 3A-3B schematically illustrate substrate supports and/or substrate support assemblies, according to other embodiments, which may be used to reduce and/or substantially prevent undesired deposition of a material layer, e.g., the carbon hard mask layer 110, onto the surfaces proximate to the circumferential edge of the substrate 100, e.g., surfaces of the bevel edge 106. Beneficially, the substrate supports and/or substrate support assemblies illustrated in FIGS. 3A-3C may be used in combination with the surface treatment methods set forth in FIG. 4 to prevent and/or substantially reduce defectivity resulting from peeling of subsequently deposited material layers from the bevel edge 106.

FIG. 3A is a schematic cross-sectional view of a portion of a substrate support assembly 300, here a substrate support 301 and an annular edge ring 303, which may be used in place of the substrate support 215 and edge ring 223 described in FIG. 2, according to one embodiment. Typically, the substrate support 301 is formed of a dielectric material and may include any one of combination of the features of the substrate support 215 including the resistive heating element 219, the cooling channels 220, and/or the chucking electrode 221 described therewith. A plasma facing surface of the substrate support 301 features a substrate supporting portion 312 and a plurality of alignment tabs 307 disposed radially outward from the substrate supporting portion 312. In some embodiments, the substrate supporting portion 312 includes a plurality of mesas 314 and a plurality of recesses 316 disposed between the mesas 314 which, with a non-active surface of the substrate 100, define a backside volume. In some embodiments, an inert heat transfer gas, such as He, is delivered to the backside volume from a heat transfer gas source (not shown) to facilitate heat transfer between the substrate and the dielectric material of the substrate support 301.

The substrate 305 has a circular shape when viewed from top down with a radius R1. Individual ones of the alignment tabs 307 are spaced apart from one another about a radius R2 from the desired center location of the substrate 100 when the substrate 100 is positioned on the substrate supporting portion 312. The radius R2 is between 0.01 mm and about 5 mm greater than the substrate radius R1. The radially inwardly facing surfaces of each of the alignment tabs 307 connect with the substrate supporting portion 312 at the radius R2 and slope upward and away (radially outwardly) therefrom. Each of the alignment tabs 307 protrude from the surface of the substrate support 301 by a height H1 of between about 0.3 mm and about 1 mm.

The alignment tabs 307 help to center the substrate 100 within a region defined by radially inward facing surfaces of an annularly shaped edge ring 303 and thus to equally space the beveled edge of the substrate 100 from the edge ring 303 about the circumference of the substrate 100. Generally, the edge ring 303 is disposed on a plasma facing surface of the substrate support 301 proximate to the circumferential edge thereof. Here, the radially inward facing surfaces of the edge ring 303 comprise a first surface 328 and a second surface 329. When the edge ring 303 is disposed on the substrate support 301, the first surface 328 is orthogonal to the surface of the substrate supporting portion 312 thereof. The second surface 329 connects to an end of the first surface 328 which is distal from the surface of the substrate support 301, and slopes upward and away (radially outward) from the first surface 328 towards and connecting to the third surface 330 of the edge ring 303. The third surface 330 is substantially parallel to the surface of the substrate supporting portion 312 of the substrate support 301 and extends radially outward from the second surface to a circumferential edge of the edge ring 303.

Here, an angle Θ1 formed by the second surface 329 and a plane parallel to the surface of the substrate supporting portion 312 of the substrate support 301 is between about 5° and about 60°, such as between about 5° and about 45°, between about 5° and about 30°, or about 60° or less, such as about 50° or less, about 45° or less, about 30° or less, about 20° or less, or about 15° or less. In the methods set forth herein the first surface 328 of the edge ring 303 is spaced apart from the circumferential edge of the substrate 100

The inner radius R3 of the edge ring 303 as measured to the first surface 328 is typically between about 1 mm and about 5 mm greater than a radius R1 of a to-be-processed substrate. For example, in some embodiments the edge ring 303 is sized to be spaced apart from the circumferential edge of the substrate 100 by a distance of less than about 5 mm, such as between about 1 mm and about 5 mm. Here, the inner surface has a height H₂ of between about 0.3 mm and about 1 mm which may be the same or different as the height H1 of the alignment tabs 307. The edge ring 303 has a height H3 of between about 1.2 mm and about 2.3 mm.

FIG. 3B is a schematic cross-section view of a portion of a substrate support assembly 310 which may be used in place of the combined substrate support 215 and edge ring 223 described in FIG. 2, according to one embodiment. Here, the substrate support assembly features a unitary body 311 of dielectric material forming the substrate supporting portion 312 and an annular shoulder 315 disposed radially outward of the substrate supporting portion and projecting upward from a surface thereof. The annular shoulder 315 has a radially inward facing surface 331 which slopes upward and away (radially outward) from the substrate supporting portion 312 to form an angle Θ2 with a plane parallel to the surface of the substrate supporting portion 312 of between about 20° and about 80°.

In some embodiments, an inner radius R4 of the shoulder 315 measured at the intersection of the inward facing surface 331 and a plane of the surface of the substrate supporting portion 312 is between about 0.01 mm and about 5 mm greater than the substrate radius R1. In some embodiments, a third surface 332 of the shoulder 315 is substantially parallel to the surface of the substrate supporting portion 312 and extends radially outward from an end of the inward facing surface, distal from the substrate supporting portion 312, to a radius R5 of between about 1 mm and about 25 mm greater than the substrate radius R1. In some embodiments, the unitary body 311 features an annular ledge 317 disposed proximate to the circumferential edge thereof. Here, the shoulder 315 has a height H4, measured from the plane of the surface of the substrate supporting portion 312 to the third surface 332, of between about 0.5 mm and about 2.5 mm. The ledge 317 has a height H5 measured from the plane of the surface of the substrate supporting portion 312 of between about 0.1 mm and about 2 mm.

FIG. 3C is a is a schematic cross-section view of a portion of a substrate support assembly 320 which may be used in place of the substrate support 215 and the edge ring 223 described in FIG. 2, according to another embodiment. Here, the substrate support assembly 320 features a unitary body 322 of dielectric material which forms the substrate supporting portion 312, an annular first shoulder 326 disposed radially outward and protruding upward therefrom, and an annular second shoulder 327 disposed about the circumference of the first shoulder 326 and protruding upward therefrom.

The first shoulder 326 features a first upper surface 350 which is connected to the substrate supporting portion 312 by a first inward facing surface 352. The first inward facing surface 352 slopes upward and away (radially outward) from the surface of the substrate supporting portion 312 to form an angle Θ3 therewith of between about 30° and about 90°. Here, an inner radius R6 of the first shoulder 326 measured at the intersection of the first inward facing surface 352 and the surface of the substrate supporting portion 312 is between about 0.01 mm and about 5 mm greater than the substrate radius R1.

In some embodiments, the first upper surface 350 has a height H6, measured from the plane of the surface of the substrate supporting portion 312 of between about 0.1 mm and about 1.2 mm. The second shoulder 327 has a second inward facing surface 353 which slopes upward and away (radially outward) from the first upper surface 350 to connect the first upper surface 350 to a second upper surface 351. Here, the first and second upper surfaces 350 and 351 respectively are substantially parallel to the surface of the substrate supporting portion 312. An inner radius R7 of the second shoulder 327 measured at the intersection of the second inward facing surface 353 and the first upper surface 350 is between about 3 mm and about 20 mm greater than the substrate radius R1. The second inward facing surface 353 and the and the annular first shoulder 326 form an angle Θ4 of between about 5° and about 60°. The second shoulder 327 has a height H7, measured from the plane of the substrate supporting portion 312, of between about 1 mm and about 2.5 mm.

FIG. 4 is a flow diagram illustrating a method 400 of treating a bevel edge 106 of a substrate 100 to improve the adhesion of a subsequently deposited material layer, e.g., a carbon hard mask layer 110, thereto. The method 400 may be performed in any suitable plasma processing chamber, such as the processing chamber 200. In some embodiments, the processing chamber 200 includes one of the substrate supports or substrate support assemblies set forth in FIGS. 3A-3C.

At activity 401 the method 400 includes positioning a substrate, e.g., the substrate 100 described in FIG. 1A, on a substrate support assembly disposed in a processing volume of a plasma processing chamber.

At activity 402 the method 400 includes optionally annealing the substrate contaminates from the surfaces of a bevel edge 106 of the substrate 100. Here, annealing the substrate 100 includes heating the substrate 100 to an anneal temperature of about 300° C. or more, 400° C. or more, 450° C. or more, or for example between about 300° C. and about 700° C. while maintaining the processing volume at a pressure of less than about 20 Torr, or between about 1 Torr and about 20 Torr. Typically, the substrate is maintained at the anneal temperature for about 60 seconds or more, such as about 90 second or more, about 120 seconds or more, or for example about 160 seconds or more.

At activity 403 the method 400 includes plasma treating the surface of the substrate. Here, plasma treating the surface of the substrate 100 includes flowing a treatment gas into the processing volume, forming treatment plasma of the treatment gas, and exposing the surface of the substrate 100 to the treatment plasma. Typically, the treatment gas is free of material deposition precursors, e.g., carbon, silicon, and/or or metal deposition precursors, and comprises one or a combination of He, Ar, NH₃, N₂, or O₂. In some embodiments, the treatment gas comprises one or a combination of gases selected to increase the hydrophilicity of the bevel surface. For example, in some embodiments the treatment gas includes Ar, N₂, or a combination thereof which produce a relatively heavy plasma activated species, compared to e.g., He alone. The relatively heavy plasma activated species desirably sputter material from the bevel surfaces of the substrate to increase the roughness and thus the hydrophilicity thereof. In some embodiments, the treatment gas includes O₂ to facilitate oxidation of the bevel surfaces of the substrate. Oxidation of the bevel surfaces of the substrate desirably increase the hydrophilicity thereof. Roughening and/or increasing the hydrophilicity of the bevel surface typically improves adhesion of a subsequently deposited material layer and thus desirably reduces peeling of the subsequently deposited material layer therefrom. In some embodiments, the treatment gas comprises O₂ and one or both of Ar and N₂.

In some embodiments, forming the treatment plasma includes applying an RF power to a showerhead disposed in the processing volume while maintaining the processing volume at a pressure of less than about 20 Torr. Here, the RF power used to form the treatment plasma is between about 0.142 Watts per cm² of substrate surface (W/cm²) and about 1.42 W/cm². For example, for a 300 mm diameter substrate the RF power used to form the treatment plasma is between about 100 W and about 1000 W. In some embodiments, the RF power used to form the treatment plasma is less than about 1.42 W/cm², such as less than about 0.71 W/cm², less than about 0.42 W/cm², or less than about 0.28 W/cm², or for example between about 0.142 W/cm² and about 0.71 W/cm². In some embodiments, the surface of the substrate is exposed to the treatment plasma for more than about 1 second, such as more than about 5 seconds, or more than about 10 seconds, or for example, between about 1 second and about 30 seconds. In some embodiments, the substrate is maintained at or above the anneal temperature of activity 402 during the duration of the plasma treatment. In other embodiments, the method 400 is performed without one of activities 402 and 403.

At activity 404 the method 400 includes chucking the substrate to the substrate support. In some embodiments, chucking the substrate to the substrate support includes maintaining the treatment plasma while applying a chucking voltage to a chucking electrode disposed in the substrate support. Here, chucking the substrate to the substrate support may be done at the beginning, during, or at the end of the duration of the plasma treatment in activity 403.

At activity 405 the method 400 includes depositing a material layer onto the surface of the substrate. Depositing a material layer onto the surface of the substrate includes flowing one or more material deposition precursors into the processing volume, forming a deposition plasma of the one or more material deposition precursors, and exposing the substrate surface to the deposition plasma to deposit the material layer thereon. Here, the one or more material deposition precursors comprise one or a combination of carbon, silicon, or metal precursors. In some embodiments, depositing the material layer comprises depositing an amorphous carbon layer, e.g., an amorphous carbon hardmask, onto the surface of the substrate. Typically, depositing an amorphous carbon layer comprises flowing a carbon-containing gas mixture into the processing volume and forming the deposition plasma therefrom.

Here, the carbon-containing gas mixture includes at least one carbon precursor. The gas mixture may further include an inert gas, a dilution gas, a nitrogen-containing gas, or combinations thereof.

In one implementation, the carbon precursor is a gaseous hydrocarbon, such as a linear hydrocarbon having a general formula CₓH_{y}, where x in the range of from 1 to 20 and y is in the range from 1 to 20. In one embodiment, the hydrocarbon is an alkane. Suitable hydrocarbons include, for example, methane (CH₄), acetylene (C₂H₂), ethylene (C₂H₄), ethane (C₂H₆), propylene (C₃H₆), and butylenes (C₄H₈), cyclobutane (C₄H₈), and methylcyclopropane (C₄H₈). Suitable butylenes include 1-Butene, 2-Butene, and isobutylene. Other suitable carbon-containing gases include carbon dioxide (CO₂) and carbon tetrafluoride (CF₄). In one embodiment, the carbon precursor comprises C₃H₆.

Suitable dilution gases such as helium (He), argon (Ar), hydrogen (H₂), nitrogen (N₂), ammonia (NH₃), or combinations thereof, among others, may be added to the gas mixture. Ar, He, and N₂ are used to control the density and deposition rate of the amorphous carbon layer. In some cases, the addition of N₂ and/or NH₃ can be used to control the hydrogen ratio of the amorphous carbon layer, as discussed below. In some embodiments, the carbon-containing gas mixture does not include a diluent.

In some embodiments, the carbon containing gas mixture further includes a nitrogen-containing gas, such as one or a combination of pyridine, aliphatic amine, amines, nitriles, or ammonia.

In some embodiments, forming the deposition plasma includes applying an RF power to a showerhead disposed in the processing volume while maintaining the processing volume at a pressure of less than about 20 Torr. Here, the RF power used to form the deposition plasma is between about 2.12 Watts per cm² of substrate surface (W/cm²) area and about 4.24 W/cm², for example for a 300 mm diameter substrate the RF power used to form the deposition plasma is between about 1500 W and about 3000 W. In some embodiments, the RF power used to form the treatment plasma is more than about 2.12 W/cm², such as more than about 2.83 W/cm², or between about 2.83 W/cm² and about 4.24 W/cm².

In some embodiments, depositing a material layer onto the substrate, such as an amorphous carbon layer, includes maintaining the substrate at a temperature between about 200° C. and about 700° C., such as between about 300° C. and about 700° C., between about 500° C. and about 700° C., or for example between about 200° C. and about 700° C. Typically, the processing volume is maintained at a pressure less than about 20 Torr. In some embodiments, an amorphous carbon layer is deposited to a thickness of between about 10 Å and about 50,000 Å, such as between about 300 Å and about 30,000 Å, or for example, between about 500 Å and about 1,000 Å.

Beneficially, the methods and processing systems described herein may be used to substantially eliminate post deposition material delamination from the bevel surfaces of a substrate (bevel peeling) thus reducing or substantially eliminating particulate defectivity associated therewith.

While the foregoing is directed to embodiments of the present disclosure, other and further embodiments of the disclosure may be devised without departing from the basic scope thereof, and the scope thereof is determined by the claims that follow.

1. A method of processing a substrate, comprising:
positioning a substrate on a substrate support assembly disposed in a processing volume of a processing chamber;
exposing the substrate to a treatment plasma, wherein the treatment plasma is formed of a treatment gas which is substantially free of carbon, silicon, and metal deposition precursors;
after exposing the substrate to the treatment plasma, applying a chucking voltage to an electrode embedded in a dielectric material of the substrate support to chuck the substrate a surface of the substrate support; and
depositing an amorphous carbon layer onto the surface of the substrate.

2. The method of claim 1, wherein exposing the substrate to the treatment plasma comprises exposing a silicon surface proximate to a circumferential edge of the substrate to the treatment plasma.

3. The method of claim 2, further comprising forming the treatment plasma, comprising:
flowing the treatment gas into the processing volume, the treatment gas comprising He, Ar, NH₃, N₂, O₂, or a combination thereof; and
igniting and maintaining the treatment plasma by applying a first RF power to a showerhead disposed in the processing volume, wherein the first RF power is about 1.42 Watts per cm² of substrate surface (W/cm²) or less.

4. The method of claim 3, wherein depositing the amorphous carbon layer onto the surface of the substrate comprises:
flowing one or more deposition material precursors into the processing volume;
igniting and maintaining a deposition plasma of the one or more deposition material precursors by applying a second RF power to the showerhead, wherein the second RF power is about 2.12 Watts per cm² of substrate surface (W/cm²) or more; and
exposing the surface of the substrate to the deposition plasma.

5. The method of claim 4, further comprising:
before depositing the amorphous carbon layer, heating the substrate to a temperature of about 300° C. or more for duration of about 60 seconds or more.

6. The method of claim 4, wherein the substrate support assembly comprises a substrate supporting portion and an annular portion extending upwardly from the substrate supporting portion, wherein the annular portion is disposed radially outward of the substrate supporting portion, and wherein the radially inward facing surface of the annular portion is sized to be spaced apart from a circumferential edge of the substrate by a distance of about 5 mm or less.

7. The method of claim 6, wherein at least a portion of the radially inward facing surface of the annular portion is sloped upward and away from a plane parallel to a surface of the substrate supporting portion to form an angle of between about 5 degrees and 60 degrees therewith.

8. The method of claim 7, wherein the substrate supporting portion comprises a portion of a surface of a substrate support and the annular portion comprises an edge ring disposed on the surface of the substrate support.

9. The method of claim 7, wherein substrate support assembly comprises a unitary body of dielectric material which forms both the substrate supporting portion and the annular portion.

10. A method of processing a substrate, comprising:
positioning a substrate on a substrate support assembly, the substrate support assembly disposed in a processing volume of a processing chamber;
heating the substrate to a temperature of about 300° C. or more; and
after maintaining the substrate at about 300° C. or more at for at least about 60 seconds, depositing an amorphous carbon layer on a surface of the substrate, comprising:
flowing one or more deposition material precursors into the processing volume;
igniting and maintaining a deposition plasma of the one or more deposition material precursors by applying an RF power to a showerhead disposed in the processing volume, wherein the RF power is about 2.12 Watts per cm² of substrate surface (W/cm²) or more; and
exposing a surface of the substrate to the deposition plasma.

11. The method of claim 10, wherein the substrate support assembly comprises a substrate supporting portion and an annular portion extending upwardly from the substrate supporting portion, wherein the annular portion is disposed radially outward of the substrate supporting portion, and wherein a radially inward facing surface of the annular portion is sized to be spaced apart from a circumferential edge of the substrate by a distance of about 5 mm or less.

12. The method of claim 11, wherein at least a portion of the radially inward facing surface of the annular portion is sloped upward and away from a plane parallel to a surface of the substrate supporting portion to form an angle of between about 5 degrees and about 60 degrees therewith.

13. The method of claim 11, wherein the substrate supporting portion comprises a portion of a surface of a substrate support and the annular portion comprises an edge ring disposed on the surface of the substrate support.

14. The method of claim 11, wherein the substrate support assembly comprises a unitary body of dielectric material which forms both the substrate supporting portion and the annular portion.

15. A processing system, comprising:
a chamber comprising a chamber lid assembly, one or more chamber sidewalls, and a chamber base which collectively define a processing volume;
a substrate support assembly disposed in the processing volume, the substrate support assembly comprising a substrate supporting portion and an annular portion extending upwardly from the substrate supporting portion, wherein the annular portion is disposed radially outward of the substrate supporting portion, and wherein a radially inward facing surface of the annular portion is sized to be spaced apart from a circumferential edge of a to-be-processed substrate by a distance of about 5 mm or less; and
a computer readable medium having instructions stored thereon for a material deposition method, the material deposition method comprising:
flowing one or more deposition material precursors into the processing volume;
igniting and maintaining a deposition plasma of the one or more deposition material precursors by applying an RF power to a showerhead of the chamber lid assembly, wherein the RF power is about 2.12 Watts per cm² of substrate surface (W/cm²) or more; and
exposing the surface of a substrate positioned on the substrate supporting portion of the substrate assembly to the deposition plasma to deposit an amorphous carbon layer thereon.

16. The processing system of claim 15, further comprising instructions stored on the computer readable medium for a plasma treatment method, the plasma treatment method comprising:
positioning the substrate on the substrate supporting portion of the substrate support assembly;
exposing a surface of the substrate to a treatment plasma, wherein the treatment plasma is formed of a treatment gas which is substantially free of carbon, silicon, and metal deposition precursors; and
after exposing the substrate to the treatment plasma, applying a chucking voltage to an electrode embedded in a dielectric material of the substrate support assembly and depositing the amorphous carbon layer onto the surface of the substrate using the deposition method.

17. The processing system of claim 15, further comprising instructions stored on the computer readable medium for a substrate annealing method, the substrate annealing method comprising:
positioning the substrate on the substrate supporting portion of the substrate supporting assembly;
heating the substrate to a temperature of about 300° C. or more; and
after maintaining the substrate at about 300° C. or more at for at least about 60 seconds, depositing the amorphous carbon layer onto a surface of the substrate using the deposition method.

18. The processing system of claim 15, wherein at least a portion of the radially inward facing surface of the annular portion is sloped upward and away from a plane parallel to a surface of the substrate supporting portion to form an angle of between about 5 degrees and about 60 degrees therewith.

19. The processing system of claim 15, wherein the substrate supporting portion comprises a portion of a surface of a substrate support and the annular portion comprises an edge ring disposed on the surface of the substrate support.

20. The method of claim 15, wherein the substrate support assembly comprises a unitary body of dielectric material which forms both the substrate supporting portion and the annular portion.
